(19) United States
(12) Patent Application Publication
(10) Pub. No.: US 2021/0173011 A1
(43) Pub. Date: Jun. 10, 2021

(54) Physics-Based Artificial Intelligence Integrated Simulation and Measurement Platform

(71) Applicants: HAMED KAJBAF, SAN JOSE, CA (US); Farideh Fazayeli, San Jose, CA (US)

(72) Inventors: HAMED KAJBAF, SAN JOSE, CA (US); Farideh Fazayeli, San Jose, CA (US)

(21) Appl. No.: 17/112,523

(22) Filed: Dec. 4, 2020

Related U.S. Application Data
(60) Provisional application No. 62/945,008, filed on Dec. 6, 2019.

(51) Int. Cl. G01R 31/3183; G06F 30/27; G06F 30/12; G06N 3/08; G06K 9/62

(52) U.S. Cl. CPC G01R 31/318357; G06F 30/27; G06F 30/12; G06K 9/6262; G06K 9/6228; G06K 9/6247; G06N 3/08

(57) ABSTRACT

Apparatus and associated methods relate to augmenting a device model identified by artificial intelligence, with measurements of physical parameters, iteratively validating and verifying the augmented model until the augmented model satisfies a quality criterion determined as a function of the artificial intelligence, and automatically synthesizing an interactive simulation and measurement environment, based on the model. The model may be identified by the artificial intelligence based on measurement of a device operating characteristic. The physical parameter measurements the model is augmented with may be determined by the artificial intelligence, based on the model. The model may include a component, sub-system, and system model, permitting validation and verification through multiple levels. Various implementations may automatically generate a measurement scenario including communication commands configured to validate and verify the augmented model. Some designs may provide visualization of synthesized simulation and measurement output generated as a function of the validated and verified augmented model.

### CROSS-REFERENCE TO RELATED APPLICATIONS

This application claims the benefit of U.S. Provisional Application No. 62/945,008, titled “Physics-Based Artificial Intelligence Integrated Simulation and Measurement Platform,” filed by Hamed Kajbaf, on 6 Dec. 2019.

This application incorporates the entire contents of the above-referenced application herein by reference.

### TECHNICAL FIELD

This disclosure relates generally to integrated simulation and modeling based on artificial intelligence (AI).

### BACKGROUND

Electronics is a field related to electrons. Electronic devices interact with electrons. An electronic device may influence an electron's behavior, and produce a technical effect. Some electronic devices manipulate electron behavior. For example, an amplifier may increase a signal's energy. Some electronic devices react to electron behavior. In an illustrative example, an attenuator may reduce a signal's energy. Various electronic devices may be active, passive, used alone, or configured in combination for use with other electronic devices.

Users of electronic devices include individuals, computer applications, organizations, government, and industry. Users may employ electronic devices to perform tasks the user may not otherwise accomplish without the electronic device. For example, a human mobile electronic device user may be able to join in a videoconference linking participants dispersed throughout the world. This facilitation may involve many complex devices interoperating through a network. Each electronic device in such a network of interoperating devices may include component, sub-system, or system level elements. For example, a single mobile communication device may include multiple computation, communication, and interface elements, configured together to perform the functions of the mobile communication device. In an illustrative example, each of the mobile communication device's component elements must operate together as designed, if the device is to function as intended.

Electronic device operating parameters include voltage, current, frequency, electromagnetic field strength, and other physical quantities. Device operating parameters may be determined based on device physics, the configuration of the device in a system, the device input, or other factors. A device behavioral model may predict device operating parameters. For example, a behavioral model may be designed to predict an electronic circuit's output determined as a function of an arbitrary input. In an illustrative example, predicting the operation of a complex device may require simulating models at component, sub-system, and system levels, to determine if the device might operate as designed before the device is physically constructed. A designer may expend significant time and effort simulating the operation of a system including many complex devices, each simulated based on multiple component, sub-system, and system models.

### SUMMARY

Apparatus and associated methods relate to augmenting a device model identified by artificial intelligence, with measurements of physical parameters, iteratively validating and verifying the augmented model until the augmented model satisfies a quality criterion determined as a function of the artificial intelligence, and automatically synthesizing an interactive simulation and measurement environment, based on the model. The model may be identified by the artificial intelligence based on measurement of a device operating characteristic. The physical parameter measurements the model is augmented with may be determined by the artificial intelligence, based on the model. The model may include a component, sub-system, and system model, permitting validation and verification through multiple levels. Various implementations may automatically generate a measurement scenario including communication commands configured to validate and verify the augmented model. Some designs may provide visualization of synthesized simulation and measurement output generated as a function of the validated and verified augmented model.

In an aspect, an apparatus is disclosed, comprising: a processor; and memory that is not a transitory propagating signal, said memory comprising instructions and data, and said memory further configured to be operably coupled to the processor, wherein the memory comprises encoded data and processor-executable program instructions, wherein the data and the instructions jointly configure and program the apparatus such that, when executed by the processor, the data and the instructions cause the apparatus to perform operations comprising: identifying the type of a device based on measuring a device operating characteristic; select a device behavioral model based on the identified device type, wherein the model is configured to model a parameter of the device; augment the model with a physical measurement of the modeled parameter identified as a function of the selected model; iteratively validate and verify the modeled parameter and the measured parameter, until an evaluation of the modeled parameter and the measured parameter satisfies a quality criterion determined as a function of an artificial intelligence; and provide access to the validated and verified model augmented with the measured physical parameter, for generating synthesized simulation and measurement output, based on the model.

The model may further comprise a physics-based model.

The operations performed by the apparatus may further comprise train the artificial intelligence with a physical model based on simulated data.

The model may further comprise a component model.

The model may further comprise a sub-system model.

The model may further comprise a system model.

Validate the modeled parameter and the measured parameter may further comprise determine if the physical parameter modeled is correct, based on measurement.

Verify the modeled parameter and the measured parameter may further comprise the measured parameter evaluated as a function of another verified measurement.

The quality criterion may be a threshold predetermined as a function of the modeled parameter.

The quality criterion may be a threshold predetermined as a function of the measured parameter.

The quality criterion may be a statistical function of the measured parameter.

The quality criterion may be a statistical function of the modeled parameter.

The quality criterion may be a function of the measured parameter evaluated in the frequency domain.

The quality criterion may be a function of the modeled parameter evaluated in the frequency domain.

The quality criterion may be a function of the measured parameter evaluated in the time domain.

The quality criterion may be a function of the modeled parameter evaluated in the time domain.

The quality criterion may be a function of bandwidth.

The quality criterion may be a function of frequency selectivity.

The quality criterion may be a function of sensitivity.

Provide access to the validated and verified model augmented with the measured physical parameter may further comprise the access provided to a graphical user interface configured to visualize the synthesized simulation and measurement output.

In another aspect, an apparatus is disclosed, comprising: a processor; and memory that is not a transitory propagating signal, said memory comprising instructions and data, and said memory further configured to be operably coupled to the processor, wherein the memory comprises encoded data and processor-executable program instructions, wherein the data and the instructions jointly configure and program the apparatus such that, when executed by the processor, the data and the instructions cause the apparatus to perform operations comprising: train an artificial intelligence with a physical model based on simulated data; identifying the type of a device under test (DUT), based on a measured device operating characteristic evaluated by the artificial intelligence; select a physics-based device behavioral model based on the identified device type, wherein the model is configured to predict a plurality of device parameters; augment the model with physical measurements of the modeled parameters, wherein the parameters the model is augmented with are identified by the artificial intelligence as a function of the selected model; iteratively validate and verify the modeled parameters and the measured parameters, until an evaluation of the modeled parameters and the measured parameters satisfies a quality criterion determined as a function of the artificial intelligence; and provide access in a graphical user interface to the validated and verified model augmented with the measured physical parameters, for generating a visualization of synthesized simulation and measurement output, based on the model.

The physics-based device behavioral model may further comprise: a component model; a sub-system model determined as a function of the component model; a system model determined as a function of the sub-system model; and a measurement model determined as a function of measurement setup.

Iteratively validate and verify the modeled parameters and the measured parameters may further comprise validate and verify based on model levels comprising: measurement, component, sub-system, and system, until the criterion is satisfied for all levels.

The measured parameter may be selected from the group consisting of current, electromagnetic field strength, frequency, impedance, and voltage.

The device under test may further comprise an amplifier.

The device under test may further comprise an attenuator.

The measured device operating characteristic may further comprise two-port insertion loss.

The measured device operating characteristic may further comprise two-port insertion gain.

In another aspect, an apparatus is disclosed, comprising: a processor; and memory that is not a transitory propagating signal, said memory comprising instructions and data, and said memory further configured to be operably coupled to the processor, wherein the memory comprises encoded data and processor-executable program instructions, wherein the data and the instructions jointly configure and program the apparatus such that, when executed by the processor, the data and the instructions cause the apparatus to perform operations comprising: train an artificial intelligence with a physical model based on simulated data; identifying the type of a device under test, based on measured device circuit network parameter evaluated by the artificial intelligence; select a physics-based device behavioral model based on the identified device type, wherein the model is configured to predict a plurality of device parameters, and wherein the model comprises: a component model; a sub-system model determined as a function of the component model; and a system model determined as a function of the sub-system model; augment the model with physical measurements of the modeled parameters, wherein the parameters the model is augmented with are identified by the artificial intelligence as a function of the selected model, and wherein the measured parameter is selected from the group consisting of current, electromagnetic field strength, frequency, impedance, and voltage; iteratively validate and verify the modeled parameters and the measured parameters based on a measurement scenario automatically prepared by the trained artificial intelligence, until an evaluation of the modeled parameters and the measured parameters for the component, sub-system, and system models satisfies a quality criterion determined as a function of the artificial intelligence; and provide access in a graphical user interface to the validated and verified model augmented with the measured physical parameters, for generating a visualization of synthesized simulation and measurement output, based on the model.

The operations performed by the apparatus may further comprise in response to determining a discrepancy between measured and modeled parameters, automatically adjust the measurement scenario.

The measurement scenario may further comprise commands configured to communicate with measurement instruments.

The artificial intelligence may be selected from the group consisting of a machine learning algorithm, an artificial neural network, and principle component analysis.

In another aspect, an apparatus is disclosed, comprising: a processor; and memory that is not a transitory propagating signal, said memory comprising instructions and data, and said memory further configured to be operably coupled to the processor, wherein the memory comprises encoded data and processor-executable program instructions, wherein the data and the instructions jointly configure and program the apparatus such that, when executed by the processor, the data and the instructions cause the apparatus to perform operations comprising: train an artificial intelligence with a physics-based behavioral model of a circuit based on simulated data generated based on the circuit model; identifying the type of a device under test as a circuit, based on measured circuit s-parameters evaluated as a function of frequency by the trained artificial intelligence; select a physics-based system-level behavioral model configured to predict a plurality of device, sub-system, and system parameters, wherein the model comprises: a circuit model; a sub-system model determined as a function of the circuit model; and a system model determined as a function of the sub-system model; augment the system-level model with physical measurements of the modeled parameters, wherein the parameters the system-level model is augmented with are identified by the artificial intelligence as a function of the circuit model, and wherein the measured parameter is selected from the group consisting of current, electromagnetic field strength, frequency, impedance, and voltage; iteratively validate and verify the modeled parameters and the measured parameters based on a measurement scenario automatically prepared by the trained artificial intelligence, until an evaluation of the modeled parameters and the measured parameters for the component, sub-system, and system models satisfies a quality criterion determined as a function of the artificial intelligence; and provide access in a graphical user interface to the validated and verified model augmented with the measured physical parameters, for generating a visualization of synthesized simulation and measurement output, based on the model.

The modeled parameters may further comprise an s-parameter.

The measured parameters may further comprise an s-parameter.

Augment the system-level model may further comprise link a physical measurement with a modeled parameter.

Provide access in the graphical user interface to the validated and verified model may further comprise a physical measurement correlated with a modeled parameter in a virtual environment.

The measurement scenario may further comprise commands configured to communicate with measurement instruments.

The measurement scenario may further comprise physical parameters measured by a vector network analyzer.

The operations performed by the apparatus may further comprise exchange a measured parameter with a simulation tool.

The operations performed by the apparatus may further comprise exchange a modeled parameter with a simulation tool.

The operations performed by the apparatus may further comprise exchange data with a Computer Aided Design (CAD) environment or a Printed Circuit Board (PCB) layout environment, to overlap with measurement or simulation data.

The present disclosure teaches a Simulation and Measurement System or Method. The Simulation and Measurement System may be a computer-implemented Simulation and Measurement Platform. The Simulation and Measurement Method may be a process implementing Simulation and Measurement Platform features. The computer-implemented Simulation and Measurement Platform may include computer hardware. The computer-implemented Simulation and Measurement Platform may include computer software. The computer hardware may include a processor and a memory. The memory may encode processor executable program instructions configured to cause the hardware to perform the disclosed Simulation and Measurement operations. The computer hardware may include interfaces designed to permit the processor to interact with and capture measurements from a device under test using various test and measurement instruments.

An exemplary Simulation and Measurement Platform implementation of a software and hardware integrated platform for a physics-based artificial intelligence (AI) configured to combine measurement and simulation may permit a user to acquire data from measurement instruments, process the data, and synthesize the measured and simulated data in a single environment. The disclosed software includes implementation of the process using computer codes, including processor executable program instructions, which may be executed on a personal computer, server, digital signal processor, cloud computing, or other computational hardware platform as may be available to one of ordinary skill. The hardware may include an interface configured to interact with or control a measurement instrument, an electrical or electronics component, the device under test, or any other physical component used in the measurement process. The measurement instrument may be a hardware apparatus configured to acquire a physical quantity and convert the physical quantity to a digital or analog signal which can communicate with the software platform. Some examples of the measurement instruments include sensors, data acquisition cards (DAQ), spectrum analyzers, oscilloscopes, vector network analyzers (VNA), time domain reflectometers (TDR), signal analyzers, and the like, as would be known to one of ordinary skill.

An exemplary Simulation and Measurement Platform may be configured to provide an integrated software and hardware environment facilitating the data measurement, simulation, visualization, correlation, and management for these design stages, with a cohesive integrated software and hardware platform capable of communicating and interacting with various devices and instruments, including, for example: measurement instruments; control electronic boards (for example, data acquisition (DAQ), analog to digital converter (ADC)/digital to analog converter (DAC), single-board computer, programmable logic controller (PLC), relay, and the like); control motorized moving structures or robotic arms; and, exchange data with simulation tools, computer-aided design (CAD), and printed circuit board (PCB) layout tools.

An exemplary Simulation and Measurement Platform software implementation may include a physics-based environment configured to perform operations such as: acquiring physical quantities based on pre-defined procedures/standards or customized procedures; self-correlating or cross-correlating various physical quantities; 0D, 1D, 2D, or 3D spatial measurement in time, frequency, or time-frequency domain; exchange data with simulation tools; post-process acquired data from measurement or simulation environments; manage large quantities of data across multiple users and over a communication network; simulate a virtual electromagnetic or circuit equivalent environment; exchange data with CAD and PCB layout environments to overlap with measurement or simulation data; provide access to a library of measurement components configured with a behavioral model designed to simulate component characteristics; and, provide an intuitive visualization and reporting environment.

An exemplary Simulation and Measurement Platform software design may be configured to facilitate an iterative validation and verification process, to provide an integrated measurement and simulation environment. The software may be configured to communicate with measurement instruments, and standard machine and/or human readable data exchange formats, such as Touchstone (SnP), IEC TR 91967-1-1, Measurement Data Format (MDF), and other formats as may be available to one of ordinary skill. The software may be configured to verify imported data in the imported environment for accuracy and compatibility with physical quantities. In a more advanced scenario, the software may be configured to permit automatically or semi-automatically adjusting simulation setup or measurement instrument settings, if discrepancies are observed. For example, the software may be configured to change meshing criteria accordingly, if the simulation tool detects a specific or predetermined pattern from measured near-field scanned data. In another example scenario, if a measurement instrument determines based on simulation results that the expected signal level is smaller than the current noise level, the measurement bandwidth or dynamic range may be adjusted accordingly. An exemplary Simulation and Measurement Platform software implementation may be configured in a modular design, to have the capability to define a measurement setup based on user-defined modules. In an illustrative example, such user-defined modules may be assembled together as templates for measurement standards, or common practices. The AI may also be implemented as library of AIs, and may be controlled by a higher level AI.

An exemplary Simulation and Measurement Platform simulation design may include implementation of a physical model in the disclosed software platform, or in a third-party software platform which can exchange data with the software platform. The physics-based feature of the software may be implemented by software configured to process the data based on the electromagnetics, physical interpretation of the quantity, the physical dimensions (units), or mathematical models representing the physics governing the device or system under test. In an illustrative example, the software may be configured to use artificial intelligence models to create an augmented physical environment (APE) through the graphical user interface (GUI) for easy correlation of physical measured data with simulated data in a virtual environment in the software platform. The virtual environment includes an implementation in the software platform representing the physical model of the hardware platform. The augmented physical environment includes linking and correlation between components of the physical quantity or the physical device under test (DUT) to the physics-based model in the virtual environment. This integration is designed to perform the data-to-information conversion even for a user without advanced training. The data may include the raw numerical data acquired by a measurement instrument. The information includes presentation of the data in a format that is easy to interpret for a human user, such as, for example, plots, diagrams, flow-charts, and the like. The disclosed software implementation facilitates training of an artificial intelligence with simulated data generated by a physics-based model. The artificial intelligence may be implemented as a machine learning (ML) algorithm. The artificial intelligence may be configured with optimizations such as, for example, artificial neural networks (ANN), embedded mapping, or principle component analysis (PCA). The trained AI may then be used to automatically prepare a measurement scenario. The measurement scenario may include a set of communication commands (for example, SCIPI) configured to communicate with measurement instruments.

An exemplary Simulation and Measurement Platform may perform systematic synthesis of measurement and simulation based on iterative validation and verification. Validation may include the software performing operations including measurement and simulation to answer the question “Is the software measuring and/or modeling the right physical quantity?” to assure the design of each measurement or simulation process and the choice of metric meets the final needs, in manufacturing, test, and/or operational conditions. Verification may include the software performing operations including measurement and simulation to answer the question “Is the software measuring and/or modeling the physical quantity correctly?” based on evaluating the measurement process with another verified measurement or simulation, and evaluating the simulation design process by another verified simulation or measurement with shared governing physics and shared evaluation metrics.

In an illustrative example, the disclosed iterative validation and verification process may be based on evaluation of each contributing component to a system level measurement and simulation. The software may then generate (or acquire from a third-party software) a physics-based behavioral model which represents the relevant electrical or electromagnetic behavior of the components or sub-systems under test and the relationship between components and the system level evaluation. Once individual components of the simulation and measurement processes are verified, the components can be used as a tool for understanding the system behavior which are otherwise difficult to characterize.

Various Simulation and Measurement Platforms may achieve one or more technical effect. For example, some Simulation and Measurement Platforms may improve a user's ease of access to system simulation. This facilitation may be a result of reducing the user's effort adjusting a device under test model and configuring the device model with a system model in the user's simulation and measurement setup. In some Simulation and Measurement Platforms, a device under test model and the device parameters to be simulated may be automatically selected for a user based on a device physical measurement evaluated by artificial intelligence. For example, the artificial intelligence may be trained with simulated data generated from a physics-based device model, and the trained artificial intelligence may identify a device model based on matching measurement of a physical device under test with the simulated data. Such automatic device under test and simulation parameter identification may reduce a user's exposure to the risk of error in model selection, and improve the user's confidence that a simulated model type matches the device under test.

Some Simulation and Measurement Platforms may reduce a user's effort obtaining verified measurement results related to a user's testing or development of an electronic system design. Such reduced effort obtaining verified measurement results may be a result of an iterative validation and verification process evaluating each contributing component to a system level measurement and simulation. Such verified measurement results may improve the user's simulation, modeling, and measurement experience. For example, verified individual components of the simulation and measurement processes may aid evaluation of complex system behavior, permitting a user to adjust system designs more quickly, and improve the accuracy or usefulness of research and development testing. In some Simulation and Measurement Platforms, a user's understanding of system behavior may be improved. Such improved understanding of system behavior may be a result of providing the user access to a visual Augmented Physical Environment (APE) correlating device under test physical measurement with simulated data in a virtual lab. For example, a user may more quickly understand the effect of a design change, based on augmented simulation visualized by the APE linking and correlating device under test physical measurements with data generated by a physics-based model in a measurement scenario generated by artificial intelligence.

In an illustrative example, design and production of an electronic board may require multiple iterations of simulation, measurement, validation, and verification, as well as pre-compliance and compliance tests. An exemplary implementation of a software and hardware integrated platform for a physics-based artificial intelligence (AI) configured to combine measurement and simulation is herein disclosed. The exemplary software implementation creates a cohesive and integrated platform designed to combine measurement and simulation, based on artificial intelligence models.

A “working example” of one aspect/embodiment of the instant invention works as follows for, inter alia, Cable Impedance Measurement and Simulation:

In one such example, the instant invention utilizes its “V-model” (FIG. 5) to iteratively use syntheses of measurement and simulation to extract the model of an HDMI cable over [a] ground plane. A cable assembly is placed on top of a metallic ground plane. The cable assembly on top of the ground plane is considered a “system” based on the V-model. Cable assembly is the “sub-system.” The metallic ground plane, the cable, and the ferrite are the “components” of the setup.
Here, the “system” would be the device being tested, here an HDMI cable over the ground plane, e.g. a wire with diameter 4 mm, substrate height 32 mm, and substrate dielectric Er 1.1; Output impedance 206 Ohms.
Here, the “sub system” is the cable assembly over the ground plane.
Here, the “component” would be, e.g., ferrite.
Here, another “component” would be the ground plane.
This example of the invention at work would have an initial Measurement Setup comprising a measuring instrument, here a vector network analyzer, and the device tested would be the HDMI cable over ground plane.
The invention then performs sub-system modeling of the cable over ground plane using third-party impedance calculator.
The simulation modeling of the system, sub-system, and components are performed in a third-party circuit simulator.
The model of the transfer impedance of the cable is extracted from the impedance calculator, which could be, for example, 206 Ohms with, for example, a time delay of 0.4 nano-seconds.
The invention then performs system, sub-system, and component level modeling using said third-party software tool.
The model of ferrite and the parameters of the model are adjusted iteratively using syntheses of measurement and simulation per the invention's apparatus and method.
Results: Measurement results are “verified” in the measurement setup with or without the ferrite on the cable assembly. Namely, the invention is therein able to compare measurements of DUT with ferrite and without ferrite.
The invention is then able to measure return loss of the cable using a vector network analyzer. Return loss can then be measured showing the various margins (e.g. between 10 and 60 dBΩ) at various frequencies (between, e.g. 1 MHz and 1 GHz).
Based on the above synthesis of the measurement and simulation, the model parameters of the ferrite on the cable assembly would be, for example, extracted as follows:

### R_{Fer}=89Ω

### L_{Fer}=293 nH

### C_{Fer}=0.2 pF

In this example, the above parameters are then visually modeled and displayed via Graphical User Interface appropriately configured to visually illustrate the above parameters in their assiciated units and ratios.

The details of various aspects are set forth in the accompanying drawings and the description below. Other features and advantages will be apparent from the description and drawings, and from the claims.

### BRIEF DESCRIPTION OF THE DRAWINGS

FIG. 1 depicts an illustrative operational scenario synthesizing an interactive simulation and measurement environment based on iteratively validating and verifying a physics-based model augmented by artificial intelligence.

FIG. 2 depicts a schematic view of an exemplary simulation and measurement network configured with an Artificial Intelligence Integrated Simulation and Measurement Platform (AIISMP) programmed and configured to synthesize an interactive simulation and measurement environment based on iteratively validating and verifying a physics-based model augmented by artificial intelligence.

FIG. 3 depicts a structural view of an exemplary AIISMP configured with an Augmented Physical Measurement and Simulation Environment Engine (APMSEE) programmed and configured to synthesize an interactive simulation and measurement environment based on iteratively validating and verifying a physics-based model augmented by artificial intelligence.

FIG. 4 depicts an exemplary integrated simulation and measurement software architecture.

FIG. 5 depicts an exemplary measurement and simulation synthesis process model.

FIG. 6 depicts an exemplary integrated simulation and measurement information flow.

FIG. 7 depicts a schematic view of an exemplary integrated simulation and measurement setup.

FIG. 8 depicts a process flow of an exemplary APMSEE programmed and configured to synthesize an interactive simulation and measurement environment based on iteratively validating and verifying a physics-based model augmented based on artificial intelligence.

FIG. 9 depicts an exemplary simulation and measurement configuration.

Like reference symbols in the various drawings indicate like elements.

### DETAILED DESCRIPTION

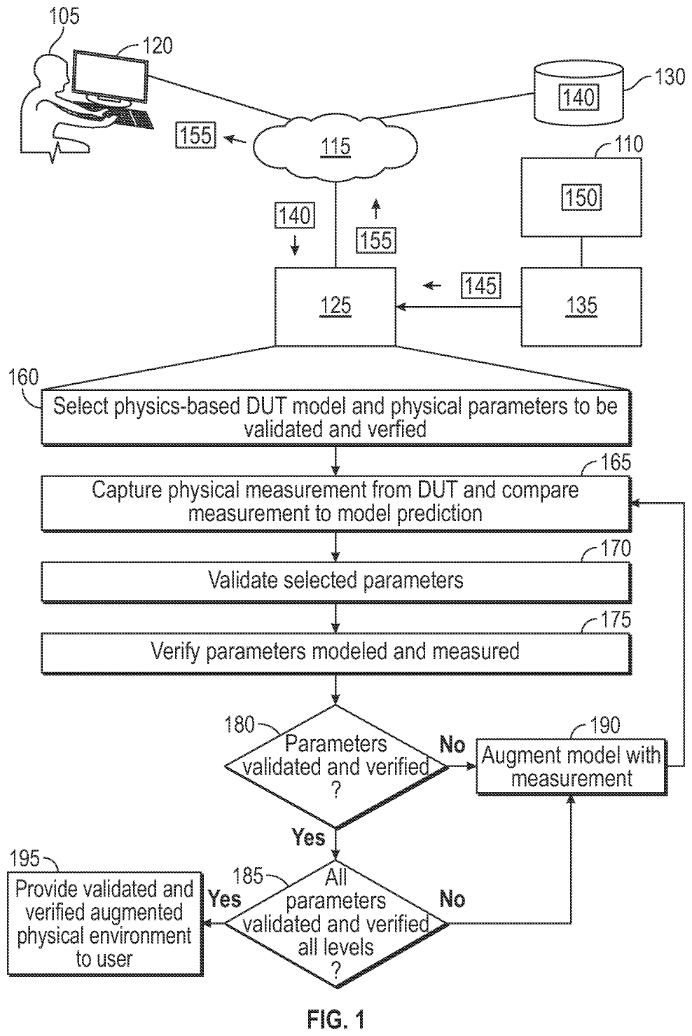

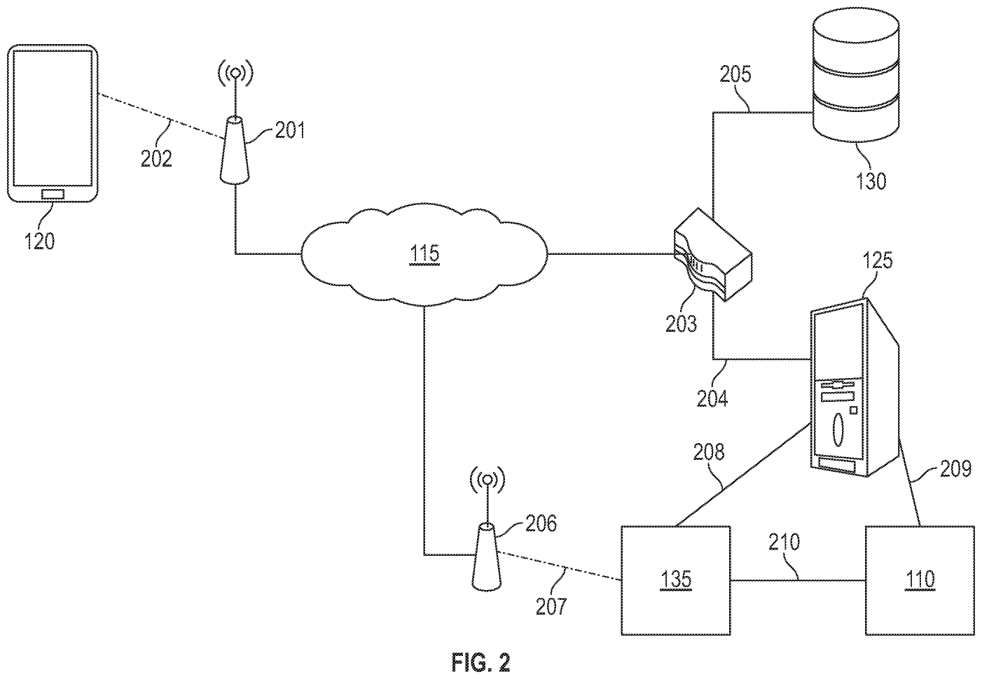

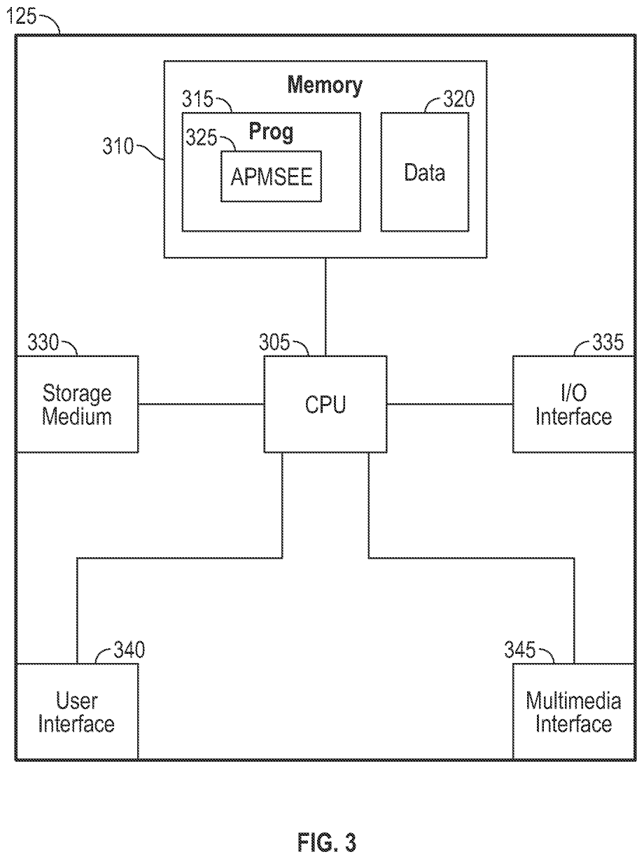

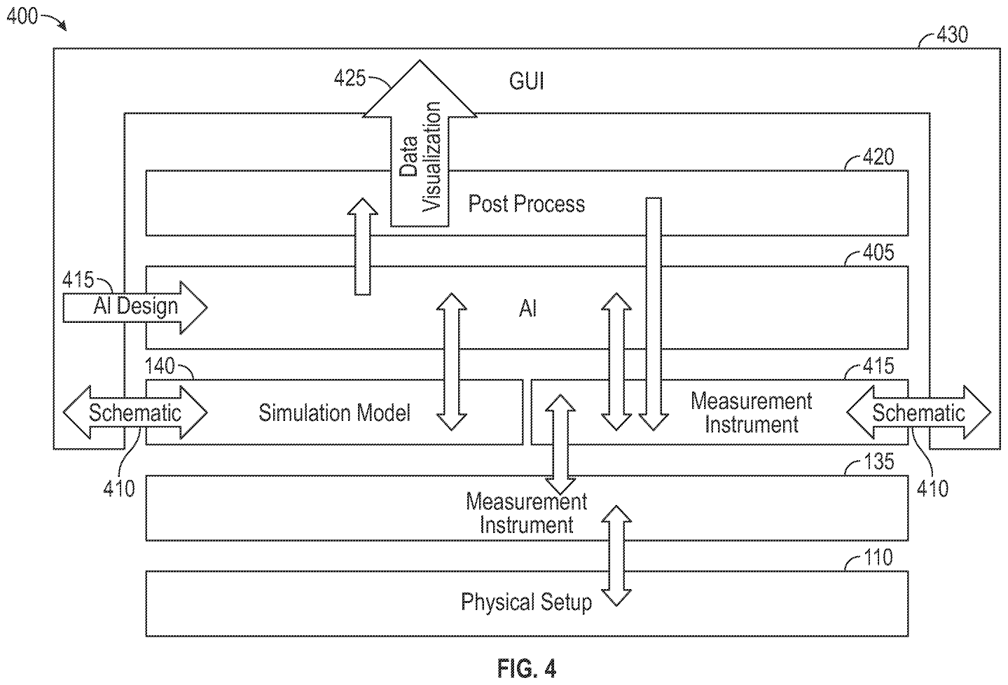

To aid understanding, this document is organized as follows. First, synthesizing an integrated simulation and measurement environment is briefly introduced with reference to FIG. 1. Second, with reference to FIGS. 2-3, the discussion turns to exemplary implementations that illustrate integrated simulation and measurement system design. Specifically, integrated simulation and measurement network and platform implementations are disclosed. Finally, with reference to FIGS. 4-9, various aspects of an exemplary Simulation and Measurement Platform design are presented to explain improvements to integrated simulation and measurement technology.

FIG. 1 depicts an illustrative operational scenario synthesizing an interactive simulation and measurement environment based on iteratively validating and verifying a physics-based model augmented by artificial intelligence. In FIG. 1, the user 105 evaluates the device under test (DUT) 110 via the network cloud 115 operably coupling the user device 120 with the Artificial Intelligence Integrated Simulation and Measurement Platform (AIISMP) 125. In the depicted implementation, the AIISMP 125 is configured to iteratively validate and verify a physics-based model of the DUT 110, until an evaluation of the modeled parameters and the measured parameters satisfies a quality criterion. The quality criterion may be determined as a function of an artificial intelligence trained with simulated data generated by a DUT 110 behavioral model. In the depicted implementation, the model database server 130 is operably coupled with the network cloud 115 to retrievably store behavioral models accessible to the AIISMP 125. In the illustrated implementation, the AIISMP 125 is operably coupled with the DUT 110 via the measurement instrument 135. In the illustrated implementation, the measurement instrument 135 is operably coupled with the AIISMP 125 to facilitate measurement and control of the DUT 110.

In an illustrative example, the AIISMP 125 may retrieve the DUT 110 model 140 from the model database server 130. The model 140 may be a behavioral model configured to predict a DUT 110 physical operating parameter. The behavioral model 140 may be a physics-based model of a component, sub-system, or system. The AIISMP 125 may augment the model 140 with measurement 145 of parameter 150 to create the synthesized integrated simulation and measurement environment 155. The AIISMP 125 may provide the synthesized integrated simulation and measurement environment 155 to the user 105 via the user device 120 user interface. The synthesized integrated simulation and measurement environment 155 may be referred to as an APE (Augmented Physical Environment).

In the depicted implementation, the AIISMP 125 generation of the DUT 110 APE begins at step 160 with the AIISMP 125 selecting the physics-based DUT 110 model 140 and physical parameters 150 to be validated and verified. The model 140 may include setup, component, sub-system, and system model levels. At step 165, the AIISMP 125 captures physical measurement 145 from the DUT 110 using the measurement instrument 135. The AIISMP 125 compares the measurement 145 to the model 140 prediction of the parameter 150. At step 170, the AIISMP 125 validates the selected parameter 150, based on the comparison. At step 175, the AIISMP 125 verifies the modeled parameter 150 based on the measurement 145. At step 180, the AIISMP 125 performs a test to determine if the parameter 150 has been validated and verified with the measurement 145. Upon a determination by the AIISMP 125 at step 180 the parameter 150 has not been validated and verified, the AIISMP 125 continues at step 190 augmenting the model 140 with the measurement 145, and the AIISMP 125 operation continues at step 165. Upon a determination by the AIISMP 125 at step 180 the parameter 150 has been validated and verified, the AIISMP 125 at step 185 performs a test to determine if all parameters have been validated and verified for all model 140 levels. Upon a determination by the AIISMP 125 at step 185 all parameters 150 have not been validated and verified for all model 140 levels, the AIISMP 125 continues at step 190 augmenting the model 140 with the measurement 145. Upon a determination by the AIISMP 125 at step 185 all parameters 150 have been validated and verified for all model 140 levels, the AIISMP 125 at step 195 provides the validated and verified augmented physical environment 155 to the user device 120. The process may repeat.

FIG. 2 depicts a schematic view of an exemplary simulation and measurement network configured with an Artificial Intelligence Integrated Simulation and Measurement Platform (AIISMP) programmed and configured to synthesize an interactive simulation and measurement environment based on iteratively validating and verifying a physics-based model augmented by artificial intelligence. In FIG. 2, according to an exemplary implementation of the present disclosure, data may be transferred to the system, stored by the system and/or transferred by the system to users of the system across local area networks (LANs) or wide area networks (WANs). The system may include numerous servers, data mining hardware, computing devices, or any combination thereof, communicatively connected across one or more LANs and/or WANs. One of ordinary skill in the art would appreciate that there are numerous manners in which the system could be configured, and implementations of the present disclosure are contemplated for use with any configuration. Referring to FIG. 2, a schematic overview of a system implementation in accordance with the present disclosure is shown. In the depicted implementation, the exemplary system includes the exemplary user device 120 configured to provide user access to an Augmented Physical Environment. In the illustrated implementation, the AIISMP 125 is a computing device configured to generate the Augmented Physical Environment based on synthesizing a simulation and measurement environment for the DUT 110. In the illustrated implementation, the DUT 110 is an electronic device subjected to synthesized simulation and measurement in the Augmented Physical Environment. The DUT 110 may be an amplifier. The DUT 110 may be an attenuator. The DUT 110 may be an equalizer. The DUT 110 may be a filter. The DUT 110 may be a coupler. In the depicted implementation, the model database server 130 is a cloud storage database configured to retrievably store behavioral models. In the illustrated implementation, the measurement instrument 135 is a measurement instrument configured to capture physical parameter measurements from the DUT 110, under the control of the AIISMP 125. In the illustrated implementation, the user device 120 is communicatively and operably coupled by the wireless access point 201 and the wireless link 202 with the network cloud 115 (for example, the Internet) to send, retrieve, or manipulate information in storage devices, servers, and network components, and exchange information with various other systems and devices via the network cloud 115. In the depicted implementation, the illustrative system includes the router 203 configured to couple the AIISMP 125 communicatively and operably to the network cloud 115 via the communication link 204. In the illustrated implementation, the router 203 also communicatively and operably couples the model database server 130 to the network cloud 115 via the communication link 205. In the depicted implementation, the measurement instrument 135 is communicatively and operably coupled with the network cloud 115 by the wireless access point 206 and the wireless communication link 207. In the illustrated implementation, the DUT 110 is operably coupled with the AIISMP 125 and the measurement instrument 135. In various implementations, one or more of: the user device 120, the AIISMP 125, the model database server 130, or the measurement instrument 135 may include an application server configured to store or provide access to information used by the system. In some implementations, one or more application server may retrieve or manipulate information in storage devices and exchange information through the network cloud 115. In various implementations, one or more of: the user device 120, the AIISMP 125, the model database server 130, or the measurement instrument 135 may include various applications implemented as processor-executable program instructions. Various processor-executable program instruction applications may also be configured in some implementations, to manipulate information stored remotely and process and analyze data stored remotely across the network cloud 115 (for example, the Internet). According to an exemplary implementation, as shown in FIG. 2, exchange of information through the network cloud 115 or other network may occur through one or more high speed connections. In some cases, high speed connections may be over-the-air (OTA), passed through networked systems, directly connected to one or more network cloud 115 or directed through one or more router. In various implementations, one or more router may be optional, and other implementations in accordance with the present disclosure may or may not utilize one or more router. One of ordinary skill in the art would appreciate that there are numerous ways any or all of the depicted devices may connect with the network cloud 115 for the exchange of information, and implementations of the present disclosure are contemplated for use with any method for connecting to networks for the purpose of exchanging information. Further, while this application may refer to high speed connections, implementations of the present disclosure may be utilized with connections of any useful speed. In an implementation example, components or modules of the system may connect to one or more of: the user device 120, the AIISMP 125, the model database server 130, or the measurement instrument 135 via the network cloud 115 or other network in numerous ways. For instance, a component or module may connect to the system i) through a computing device directly connected to the network cloud 115, ii) through a computing device connected to the network cloud 115 through a routing device, or iii) through a computing device connected to a wireless access point. One of ordinary skill in the art will appreciate that there are numerous ways that a component or module may connect to a device via network cloud 115 or other network, and implementations of the present disclosure are contemplated for use with any network connection method. In various examples, one or more of: the user device 120, the AIISMP 125, the model database server 130, or the measurement instrument 135 could include a personal computing device, such as a smartphone, tablet computer, wearable computing device, cloud-based computing device, virtual computing device, or desktop computing device, configured to operate as a host for other computing devices to connect to. One or more communications means of the system may be any circuitry or other means for communicating data over one or more networks or to one or more peripheral device attached to the system, or to a system module or component. Appropriate communications means may include, but are not limited to, wireless connections, wired connections, cellular connections, data port connections, Bluetooth® connections, near field communications (NFC) connections, or any combination thereof. One of ordinary skill in the art will appreciate that there are numerous communications means that may be utilized with implementations of the present disclosure, and implementations of the present disclosure are contemplated for use with any communications means.

FIG. 3 depicts a structural view of an exemplary AIISMP configured with an Augmented Physical Measurement and Simulation Environment Engine (APMSEE) programmed and configured to synthesize an interactive simulation and measurement environment based on iteratively validating and verifying a physics-based model augmented by artificial intelligence. In FIG. 3, the block diagram of the exemplary AIISMP 125 includes processor 305 and memory 310. The processor 305 is in electrical communication with the memory 310. The depicted memory 310 includes program memory 315 and data memory 320. The depicted program memory 315 includes processor-executable program instructions implementing the APMSEE (Augmented Physical Measurement and Simulation Environment Engine) 325. The illustrated program memory 315 may encode processor-executable program instructions configured to implement an OS (Operating System). The OS may include processor executable program instructions configured to implement various operations when executed by the processor 305. The OS may be omitted. The illustrated program memory 315 may encode processor-executable program instructions configured to implement various Application Software. The Application Software may include processor executable program instructions configured to implement various operations when executed by the processor 305. The Application Software may be omitted. In the depicted implementation, the processor 305 is communicatively and operably coupled with the storage medium 330. In the depicted implementation, the processor 305 is communicatively and operably coupled with the I/O (Input/Output) interface 335. In the depicted implementation, the I/O interface 335 includes a network interface. The network interface may be a wireless network interface. The network interface may be a Wi-Fi interface. The network interface may be a Bluetooth® interface. The AIISMP 125 may include more than one network interface. The network interface may be a wireline interface. The network interface may be omitted. The I/O interface 335 may include electronic circuitry designed to permit processor 305 communication and control of various measurement instruments. In the depicted implementation, the processor 305 is communicatively and operably coupled with the user interface 340. In the depicted implementation, the processor 305 is communicatively and operably coupled with the multimedia interface 345. In the illustrated implementation, the multimedia interface 345 includes interfaces adapted to input and output of audio, video, and image data. The multimedia interface 345 may include one or more still image camera or video camera. Useful examples of the illustrated AIISMP 125 include, but are not limited to, personal computers, servers, tablet PCs, smartphones, or other computing devices. Multiple AIISMP 125 devices may be operably linked to form a computer network in a manner as to distribute and share one or more resources, such as clustered computing devices and server banks/farms. Various arrangements of such general-purpose multi-unit computer networks suitable for implementations of the disclosure, their typical configuration, and standardized communication links are well known to one skilled in the art, as explained in more detail in the foregoing FIG. 2 description. An exemplary AIISMP 125 design may be realized in a distributed implementation. Some AIISMP 125 designs may be partitioned between a client device, such as, for example, a phone, and a more powerful server system, as depicted, for example, in FIG. 2. A AIISMP 125 partition hosted on a PC or mobile device may choose to delegate some parts of computation, such as, for example, machine learning or deep learning, to a host server. A client device partition may delegate computation-intensive tasks to a host server to take advantage of a more powerful processor, or to offload excess work. Some AIISMP 125 devices may be configured with a mobile chip including an engine adapted to implement specialized processing, such as, for example, neural networks, machine learning, artificial intelligence, image recognition, audio processing, or digital signal processing. Such an engine adapted to specialized processing may have sufficient processing power to implement some AIISMP 125 features. However, an exemplary AIISMP 125 may be configured to operate on a device with less processing power, such as, for example, various gaming consoles, which may not have sufficient processor power, or a suitable CPU architecture, to adequately support AIISMP 125. Various implementations configured to operate on a such a device with reduced processor power may work in conjunction with a more powerful server system.

FIG. 4 depicts an exemplary integrated simulation and measurement software architecture. In FIG. 4, the illustrated software architecture 400 includes the artificial intelligence (AI) 405 governing the simulation model 140 augmentation with parameter measurements. The simulation model 140 of the physical setup and device under test 110 may be generated as a function of the schematic 410 by the AI design 415. In the depicted implementation, the AI 405 governs the model 140 selection and augmentation with parameter measurements captured by the measurement instrument 135 from the physical setup and device under test 110. In the illustrated implementation, the model 140 augmented with the parameter measurements is prepared by post process 420 for data visualization 425 and presented as a synthesized integrated simulation and measurement environment in the graphical user interface 430.

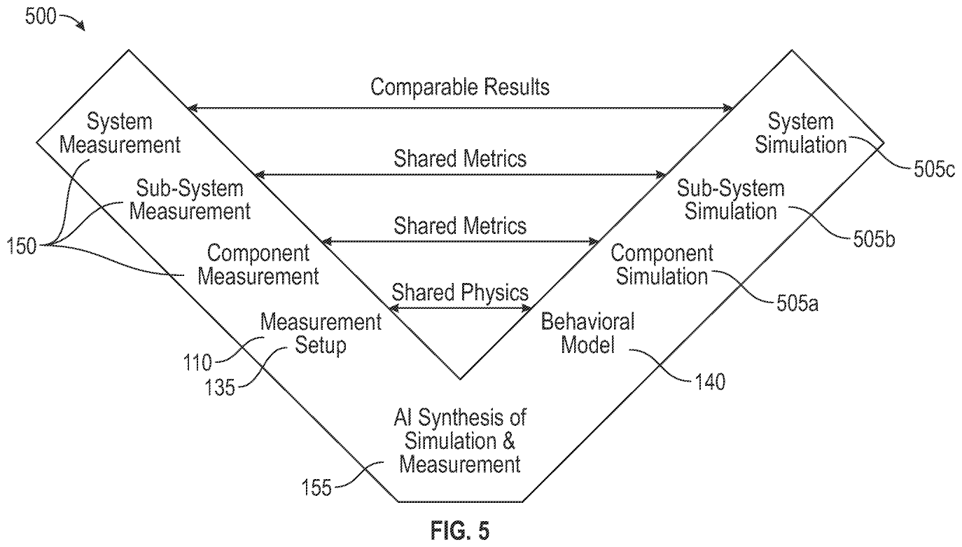

FIG. 5 depicts an exemplary measurement and simulation synthesis process model. In FIG. 5, the illustrated process V-model 500 defines the Simulation and Measurement Platform software design that integrates the measured parameters 150, component simulation 505a, sub-system simulation 505b, and system simulation 505c to create the synthesized integrated simulation and measurement environment 155. An exemplary software architecture is described with reference to FIG. 4. The design and usage of the depicted process V-model 500 disclosed herein is distinct from the design and usage of V-models known in technical fields related to systems development, at least because the depicted process V-model 500 defines an iterative process, in stark contrast with a more conventional systems development V-model, which may be interpreted only sequentially, for example, from left to right. In an illustrative example, a process defined by the depicted process V-model 500 diagram may be interpreted as beginning from the bottom of the V-model 500 with measurement setup behavioral modeling, and proceeding up in the V-model 500 diagram with component simulation 505a, sub-system simulation 505b, and system simulation 505c. Thus, the depicted process V-model 500 defines a process iteratively validating and verifying at multiple levels from bottom to top, and augmenting the model until AI determines comparable results are achieved.

In the depicted implementation, the process V-model 500 includes the repetition of each step to fulfill the evaluation of validation and verification processes. In the illustrated implementation, the evaluation of validation and verification based on the behavioral model 140 is validated and verified based on shared physics and measurements 150 captured by the measurement instrument 135 from the device under test 110. In the depicted implementation, the evaluation of validation and verification based on shared metrics is repeated for the component simulation 505a, the sub-system simulation 505b, and the system simulation 505c until comparable results are obtained. The determination that comparable results have been obtained between the system measurement and system simulation may be based on a quality criterion evaluated by an artificial intelligence. Additionally, verified measurement results can be used as inputs to simulation tools, to increase the accuracy and efficiency of the simulation process. In this process V-model 500 combining the measurement and simulation, the behavioral model 140 in simulation may be physics-based and share the same governing physics as the measurement setup. As shown in FIG. 4, the software with the help of AI, will fill the gap between simulation and measurement by linking the components of the physical model and the measurement setup. The software provides an APE (Augmented Physical Environment) to help the user to perform the measurement accurately. This criteria may be difficult to achieve in some simulation scenarios. In such conditions, more verification (under various conditions) may be needed to guarantee accurate behavior of the model within the scopes of the measurement of interest. The choice of metric also needs to be based on a quantity which is directly measurable (such as electromagnetic field strength, voltage, current, impedance, s-parameters, and the like). Under some circumstances, such as when the quantity of interest is indirectly measured, more verification may be needed.

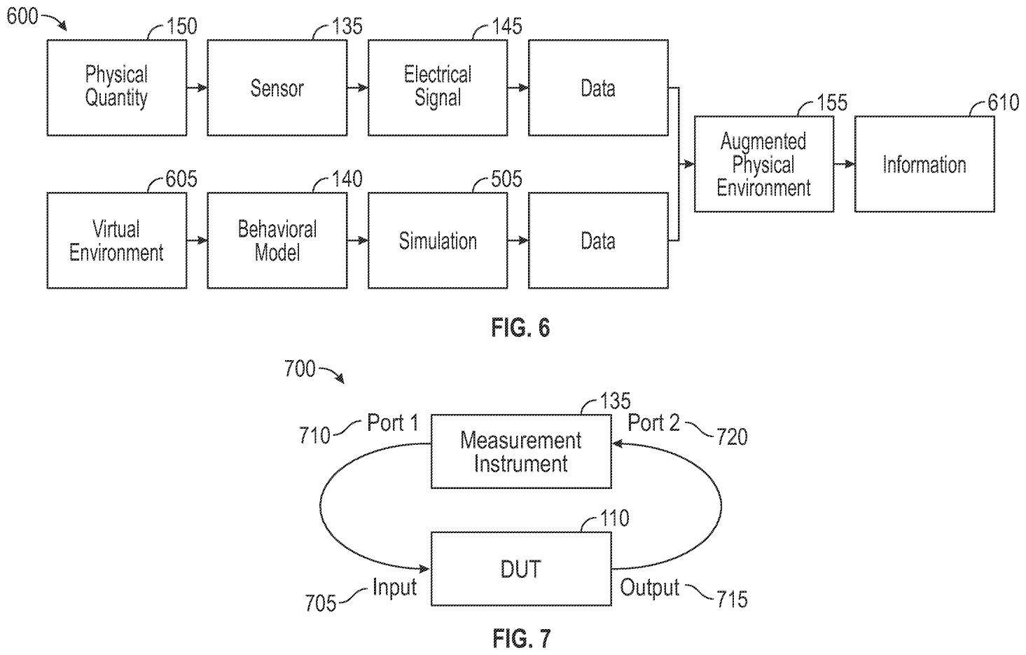

FIG. 6 depicts an exemplary integrated simulation and measurement information flow. In FIG. 6, the exemplary Simulation and Measurement Platform information flow 600 depicts the integration of the physical quantity represented by the measured parameter 150 with simulation data generated based on the behavioral model 140. The measured parameter 150 is integrated with the simulation data in in the virtual environment 605. The measurement instrument 135 sensor converts the physical quantity to the electrical signal represented by measurement 145 data. Simulation 505 generates modeled data based on the behavioral model 140. The measurement data and the modeled data are combined to form the synthesized integrated simulation and measurement environment information 610.

FIG. 7 depicts a schematic view of an exemplary integrated simulation and measurement setup. In FIG. 7, the setup schematic 700 depicts an exemplary synthesis of measurement and simulation scenario. The software and hardware implementation of the exemplary measurement scenario is described. The goal of the illustrated scenario is to measure the transfer function of the DUT 110. In the illustrated example, DUT 110 may be a radio frequency (RF) attenuator or amplifier. The transfer function of the DUT 110 will be measured using the measurement instrument 135. In the depicted example, the measurement instrument 135 is a vector network analyzer (VNA). A VNA is a measurement instrument capable of measuring scattering parameters (S-parameters) of a device under test (DUT). In the depicted example, the loss of an attenuator or gain of an amplifier is measured based on measuring two port insertion loss (or gain) also known as S21 parameter as a function of frequency. The depicted setup schematic 700 of the physical measurement for this scenario includes input 705 of the DUT 110 connected to port 1 710 of the VNA and output 715 of DUT 110 connected to port 2 720 of the VNA using coaxial cables. Port 1 710 of the VNA transmits an RF signal toward the DUT 110 and port 2 720 of the VNA receives the attenuated (in case DUT 110 is an attenuator) or amplified (in case DUT 110 is an amplifier) signal from the DUT 110. The ratio of the received voltage on port 2 720 over the transmitted voltage on port 1 710 is defined as S21 parameter.

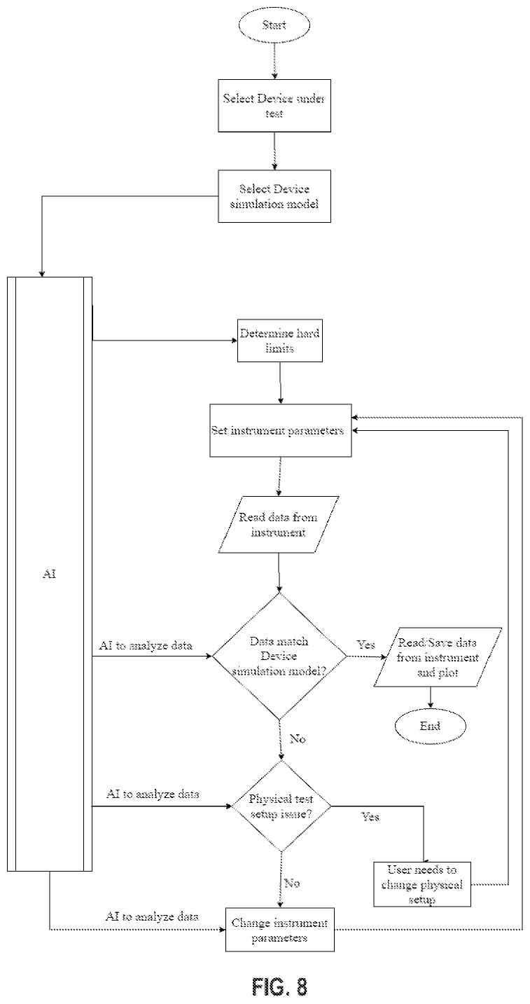

FIG. 8 depicts a process flow of an exemplary APMSEE programmed and configured to synthesize an interactive simulation and measurement environment based on iteratively validating and verifying a physics-based model augmented based on artificial intelligence. In FIG. 8, the depicted method is given from the perspective of the Augmented Physical Measurement and Simulation Environment Engine (APMSEE) 325 implemented via processor-executable program instructions executing on the AIISMP 125 processor 305, depicted in FIG. 3. In the illustrated implementation, the APMSEE 325 executes as program instructions on the processor 305 configured in the APMSEE 325 host AIISMP 125, depicted in at least FIG. 1, FIG. 2, and FIG. 3. In some implementations, the APMSEE 325 may execute as a cloud service communicatively and operatively coupled with system services, hardware resources, or software elements local to and/or external to the APMSEE 325 host AIISMP 125. The illustrated process 800 is a non-limiting illustrative example of a Simulation and Measurement Platform implementation's measurement of the S21 parameter of an attenuator or amplifier using a VNA. Other measurements of other devices are contemplated, as would be recognized by one of ordinary skill.

The depicted method 800 begins at step 805 with the processor 305 performing a test to determine if the device under test is an attenuator or an amplifier. The determination may be based on measurement data evaluated as a function of an AI trained with simulated data generated by a model of a known device type.

Upon a determination by the processor 305 at step 805 the device under test is an attenuator, the method continues at step 810 with the processor 305 selecting an attenuator simulation model, and the method continues at step 820.

Upon a determination by the processor 305 at step 805 the device under test is an amplifier, the method continues at step 815 with the processor 305 selecting an amplifier simulation model, and the method continues at step 820.

At step 820 the processor 305 activates the trained AI to govern the Simulation and Measurement Platform measurement scenario based on modeled and measured parameters, and the method continues at step 825.

At step 825, the processor 305 receives from the AI hard limits for modeled and measured parameters determined by the AI.

At step 830, the processor 305 sets measurement instrument parameters. In this example scenario, the software communicates with the VNA using a communication protocol such as Standard Commands for Programmable Instruments (SCPI). In some implementations, the user may set in the software that the parameter of interest is an S-parameter and the measurement instrument is a VNA. In this example, the AI configures the initial parameters in the software platform to transmit a pilot signal from port 1 and receive a signal from port 2 of the VNA. The measurement instrument parameters set by the processor 305 may be based on the hard parameter limits received by the processor 305 from the AI. The software may then be reconfigured according to the new information, with the capability of user interaction to change the parameters. This process may be implemented by machine learning algorithms such as an active learning model. The measurement instrument parameters set by the processor 305 may include, for example, Start frequency, Stop frequency, IF bandwidth, Power, Number of points, S-parameter, Sweep type, or other parameters as may be known to one of ordinary skill.

At step 835, the processor 305 reads data from the instrument. The data read by the processor 305 from the instrument may be measurement data captured from the device under test. The processor 305 activates the AI to analyze the data read from the instrument. After the initial parameters on the instrument are set, the software reads the S-parameter of the DUT. Another layer of AI performs an analysis on the acquired data. This analysis is performed to confirm the measured S-parameter follows the expected values based on the simulated physical model. In this example, the AI analyzes the transmitted and received pilot signal to understand the physical property of the DUT, and match it to a physical component based on the simulated parameters of the DUT. In this scenario the simulation model of the attenuator is the mathematical attenuation factor of the magnitude of a sinusoidal signal on the output of the attenuator compared to the input of the attenuator. In the case of the amplifier, the simulation model is the mathematical amplification factor of the magnitude of a sinusoidal signal on the output of the amplifier compared to the input of the amplifier. In this case, the AI provides a probabilistic prediction of the type of the DUT and the probabilistic prediction of the parameters of the DUT such as gain or loss. The AI provides a confidence level for the predicted parameters based on the pilot signal.

At step 840, the processor 305 performs a test to determine if the data read from the instrument by the processor 305 at step 835 matches the simulation model selected based on the determination by the processor 305 at step 805. The model may be an attenuator or amplifier simulation model. Upon a determination by the processor 305 at step 840 the data read from the instrument matches the selected model, the method continues at step 845. Upon a determination by the processor 305 at step 840 the data read from the instrument does not match the selected model, the processor 305 activates the AI to analyze the data, and the method continues at step 850.

At step 845, the processor 305 reads and saves the data read from the instrument, plots the data per the user's configuration, and the method ends.

At step 850, the processor 305 performs a test to determine if a physical test setup issue has been detected, based on the AI data analysis performed by the processor 305 at step 840. The AI may decide if the mismatch is due to improper parameters on the instruments, or due to an issue in the physical measurement setup. In the case of improper parameters, the AI may reconfigure the settings in the instrument, and repeat the data acquisition process described above. Upon a determination by the processor 305 at step 850 that a physical test setup issue has been detected, the method continues at step 860. Upon a determination by the processor 305 at step 850 that a physical test setup issue has not been detected, the method continues at step 855.

At step 855, the processor 305 activates the AI to analyze the data read from the instrument, and the processor 305 changes the instrument parameters based on the AI data analysis. The method continues at step 830.

At step 860, the processor 305 indicates the user needs to change the physical setup. The processor 305 may notify the user to make proper modification in the setup, and the software may repeat the data acquisition process described above. The method continues at step 830.

In some implementations, the method may repeat. In various implementations, the method may end.

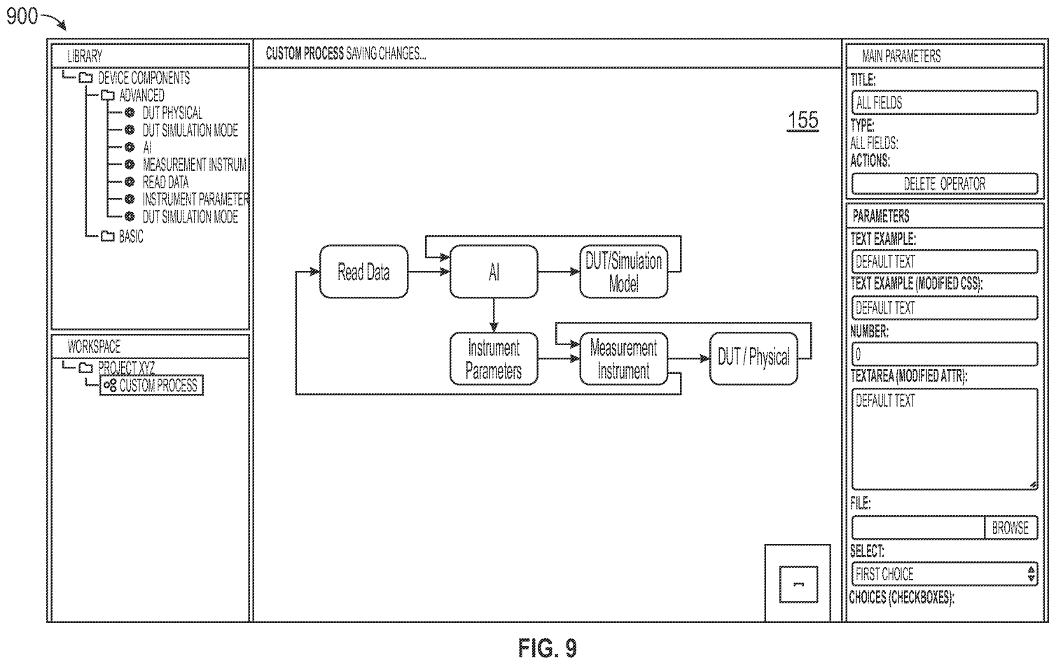

FIG. 9 depicts an exemplary simulation and measurement configuration. In FIG. 9, the exemplary simulation and measurement configuration 900 depicts the software implementation configured to measure the loss of an RF attenuator or the gain of an amplifier visualized by the synthesized integrated simulation and measurement environment 155.

The reference numbers and their respective elements depicted by the Drawings are summarized as follows.
105 user
110 device under test (DUT)
115 network cloud
120 user device
125 AIISMP (Artificial Intelligence Integrated Simulation and Measurement Platform)
130 model database server
135 measurement instrument
140 model
145 measurement
150 parameter
155 synthesized integrated simulation and measurement environment
160 simulation and measurement synthesis step 160
165 simulation and measurement synthesis step 165
170 simulation and measurement synthesis step 170
175 simulation and measurement synthesis step 175
180 simulation and measurement synthesis step 180
185 simulation and measurement synthesis step 185
190 simulation and measurement synthesis step 190
195 simulation and measurement synthesis step 195
201 wireless access point
202 wireless link
203 router
204 communication link
205 communication link
206 wireless access point
207 wireless communication link
305 processor
310 memory
315 program memory
320 data memory
325 APMSEE (Augmented Physical Measurement and Simulation Environment Engine)
330 storage medium
335 I/O interface
340 user interface
345 multimedia interface
400 software architecture
405 artificial intelligence
410 schematic
415 artificial intelligence design
420 post process
425 data visualization
430 graphical user interface
500 process V-model
505 simulation
505a component simulation
505b sub-system simulation
505c system simulation
600 information flow
605 virtual environment
610 information
700 setup schematic
705 input
710 port 1
715 output
720 port 2
800 APMSEE process flow
900 simulation and measurement configuration

Although various features have been described with reference to the Drawings, other features are possible.

In the present disclosure, various features may be described as being optional, for example, through the use of the verb “may.” For the sake of brevity and legibility, the present disclosure does not explicitly recite each and every permutation that may be obtained by choosing from the set of optional features. However, the present disclosure is to be interpreted as explicitly disclosing all such permutations. For example, a system described as having three optional features may be implemented in seven different ways, namely with just one of the three possible features, with any two of the three possible features or with all three of the three possible features. The respective implementation features, even those disclosed solely in combination with other implementation features, may be combined in any configuration excepting those readily apparent to the person skilled in the art as nonsensical.

A number of implementations have been described. Nevertheless, it will be understood that various modifications may be made. For example, the steps of the disclosed techniques may be performed in a different sequence, components of the disclosed systems may be combined in a different manner, or the components may be supplemented with other components. Accordingly, other implementations are contemplated, within the scope of the following claims.

1. An apparatus comprising:
a processor; and
memory that is not a transitory propagating signal, said memory comprising instructions and data, and said memory further configured to be operably coupled to the processor, wherein the memory comprises encoded data and processor-executable program instructions, wherein the data and the instructions jointly configure the apparatus such that, when executed by the processor, the data and the instructions cause the apparatus to perform operations comprising:
an external device under test;
identifying the type of external device under test by measuring at least one device operating characteristic;
selecting a device behavioral model based on the device under test, therein creating a modeled parameter of the device;
augmenting the model with a physical measurement of the modeled parameter identified as a function of the selected model;
iteratively and repeatedly validating and verifying the modeled parameter and the measured parameter until an evaluation of the modeled parameter and the measured parameter satisfies a quality criterion determined as a function of an artificial intelligence tool; and
providing access to the validated verified model augmented with the measured physical parameter, based on the model, said access being useful for generating a synthesized simulation and measurement output.

2. The apparatus of claim 1, wherein the model further comprises a physics-based model.

3. The apparatus of claim 1, wherein the operations performed by the apparatus further comprise train the artificial intelligence tool with a physical model based on simulated data.

4. The apparatus of claim 1, wherein the model further comprises a component model.

5. The apparatus of claim 1, wherein the model further comprises a sub-system model.

6. The apparatus of claim 1, wherein the model further comprises a system model.

7. The apparatus of claim 1, wherein the modeled parameter and measured parameter together determine whether the model is correct, based on physical measurement.

8. The apparatus of claim 1, wherein the measured and modeled parameters further comprise a measured parameter evaluated as a function of another verified simulation measurement.

9. The apparatus of claim 1, wherein access to the augmented model is shown via a graphical user interface configured to visually illustrate the synthesized simulation and the measurement output.

10. A device testing apparatus comprising:
a processor; and
a device under test (“DUT”); and
a memory that is not a transitory propagating signal, the memory configured to be operably coupled to the processor, wherein the memory comprises encoded data and processor executable program instructions, wherein the data and instructions configure and program the apparatus that the instructions when executed by the processor cause the apparatus to perform operations comprising:
training an artificial intelligence tool with a physical model based on simulated data;
identifying the type of a device under test based on a measured device operating characteristic evaluated by the artificial intelligence tool;
selecting a physics-based device behavioral model based on the identified DUT type, wherein the model is configured to predict a plurality of device parameters;
augmenting the model with physical measurements of the modeled parameters, wherein the parameters augmented are identified by the artificial intelligence tool as a function of the selected model;
iteratively and repeatedly validating and verifying the modeled parameters and the measured parameters until an evaluation of the modeled parameters and the measured parameters satisfy a quality criterion determined as a function of the artificial intelligence tool; and
providing access via a graphical user interface to the augmented models, therein generating a visual illustration of a synthesized simulation measurement output.

11. The apparatus of claim 10, wherein the physics-based device behavioral model further comprises: a component model, a sub-system model determined as a function of the component model, a system model determined as a function of the sub-system model, and a measurement model determined as a function of the measurement setup.

12. The apparatus of claim 10, wherein the modeling further delineates model levels comprising: measurement levels, component levels, sub-system levels, and system levels until the criterion is satisfied for all levels.

13. The apparatus of claim 10, wherein the measured parameter is selected from the group consisting of electrical current, electromagnetic field strength, frequency, impedance, voltage, time, distance, and temperature.

14. The apparatus of claim 10, wherein the measurement instrument is selected from the group consisting of current probe, electric probe, magnetic probe, near-field probe, antenna, spectrum analyzer, signal analyzer, vector network analyzer, scalar network analyzer, voltage probe, oscilloscope, data acquisition card, time-domain reflectometer, temperature sensor, and noise figure analyzer.

15. The apparatus of claim 10, wherein the device is selected from the group consisting of radio frequency device, digital circuit, analog circuit, mixed-signal circuit, and antenna.

16. An apparatus comprising:
a processor; and
a device under test; and
a memory that is not a transitory propagating signal, the memory configured to be operably coupled to the processor, wherein the memory comprises encoded data and processor executable program instructions, wherein the data and instructions configure and program the apparatus that the instructions when executed by the processor cause the apparatus to perform operations comprising:
training an artificial intelligence tool with a physical model based on simulated data;
identifying the type of a device under test, based on a measured device parameter selected from the group consisting of current, electromagnetic field strength, frequency, impedance, voltage, time, distance, and temperature evaluated by the artificial intelligence tool;
selecting a physics-based device behavioral model based on the identified device type, wherein the model is configured to predict a plurality of device parameters, and wherein the model comprises: a component model; a sub-system model determined as a function of the component model; and a system model determined as a function of the sub-system model;
augmenting the model with physical measurements of the modeled parameters, wherein the parameters are identified by the artificial intelligence tool as a function of the selected model, and wherein the measured parameter is selected from the group consisting of electrical current, electromagnetic field strength, frequency, impedance, voltage, time, distance, and temperature;
iteratively and repeatedly validating and verifying the modeled parameters and the measured parameters based on a measurement scenario automatically prepared by the trained artificial intelligence tool until an evaluation of the modeled parameters and the measured parameters for the component, sub-system, and system models satisfies a quality criterion determined as a function of the artificial intelligence tool; and
providing access via graphical user interface to the validated verified model augmented with the measured physical parameters, for the purpose of generating a visualization of the resulting synthesized simulation and measurement output based on the apparatus' model.

17. The apparatus of claim 16, wherein the apparatus automatically adjusts the measurement scenario by responding to a discrepancy between measured parameters and modeled parameters.

18. The apparatus of claim 16, wherein the apparatus further communicates with the instruments it is measuring via commands.

19. The apparatus of claim 16, wherein the artificial intelligence tool is selected from the group consisting of a machine learning algorithm, an artificial neural network, embedded mapping, and a principle component analysis.

20. An electronic-device testing apparatus comprising:
a processor; and
an electronic device under test; and
memory that is not a transitory propagating signal, the memory configured to be operably coupled to the processor, wherein the memory comprises encoded data and processor-executable program instructions, wherein the memory causes the apparatus to:
train an artificial intelligence tool with a physical model based on simulated data;
identify the type of electronic device under test by using a circuit network parameter measuring instrument, said circuit network parameter then being evaluated by the artificial intelligence tool;
select a physics-based device behavioral model based on the type of electronic device therein identified, wherein the model is configured to predict a plurality of the device's parameters, wherein the model further comprises a component model, a system model and a sub-system model;
augment the component model with physical measurements of the modeled electromagnetic parameters, wherein these parameters are identified by the artificial intelligence tool as a function of the selected model, and wherein the measured parameter is selected from the group consisting of current, electromagnetic field strength, frequency, impedance, voltage, time interval, distance, and temperature;
iteratively and repeatedly validate and verify the modeled parameters and the measured parameters based on a measurement scenario automatically prepared by the trained artificial intelligence tool until an evaluation of the modeled parameters and the measured parameters for the component system models satisfies a quality criterion determined as a function of the artificial intelligence tool; and
provide access via graphical user interface to the validated verified model augmented with the measured physical parameters for the purpose of generating a visualization of the resulting synthesized simulation and measurement output based on the apparatus' model.

21. The apparatus of claim 20, wherein the artificial intelligence tool is a machine learning algorithm.

22. The apparatus of claim 20, wherein the artificial intelligence tool is an artificial neural network.

23. The apparatus of claim 20, wherein the artificial intelligence tool is embedded mapping.

24. The apparatus of claim 20, wherein the artificial intelligence tool is a principle component analysis.
